(19) United States
(12) Patent Application Publication
(10) Pub. No.: US 2026/0255919 A1
(43) Pub. Date: Aug. 27, 2026

(54) METHOD AND APPARATUS FOR DETERMINING A POSITIONING ERROR OF A PICKABLE COMPONENT

(71) Applicant: BESI SWITZERLAND AG, Steinhausen (CH)

(72) Inventors: Florian SPEER, Steinhausen (CH); Bernhard FAHRINGER, Steinhausen (CH)

(21) Appl. No.: 19/144,921

(22) PCT Filed: Jan. 1, 2024
(86) PCT No.: PCT/IB2024/050007

§ 371 Date: Jun. 30, 2025

(30) Foreign Application Priority Data
Dec. 31, 2022 (DE) 10 2022 135 081.9

(51) Int. Cl. H10P 72/50; H10W 46/00; H10W 72/00

(52) U.S. Cl. CPC H10P 72/53; H10W 46/301; H10W 72/07173; H10W 72/07178; H10W 72/07183

(57) ABSTRACT

A method and apparatus are provided for determining a positioning error of a pickable component, the apparatus 100 comprising a component holder 130 for releasably attaching to the component 600, the method comprising using a look-up camera 410 at a component exchange position to make a first image 720 of a first component mark, attaching the component to a gripper 160, releasing the component, using the look-up camera to make a second image 730 of a second component mark, and determining a position error using the second image with the first image.

### TECHNICAL AREA

The present disclosure relates to an apparatus or a method for determining a positioning error of one or more pickable components, such as dies or electrical components, before placement on one or more substrates. Optionally, the picking may occur before bonding with the one or more substrates in a bonding apparatus.

### BACKGROUND

From the state-of-the-art, similar apparatus and components are known, such as described in US 2009/0070992 A1. This patent application describes a semiconductor mounting apparatus containing a pick and place system having a bonding head, which has a first drive system and a second drive system for displacing the bonding head in a predetermined direction. The first drive system has a first pivot arm and a first stationary situated drive, which is used to pivot the pivot arm back-and-forth within a predefined pivot range. The second drive system is mounted on the pivot arm and comprises a stationary situated electric motor.

During semiconductor assembly, components are often transferred or changed between manipulators and actuators arranged to move components between stations for loading, unloading or processing. To detect the position of components at these stations, one or more inspection cameras are typically provided, and measurements made with the cameras are used to determine the destination for a manipulator or actuator to move to pick up or to place the components. However, unexpected position errors still frequently occur, affecting the quality of the semiconductor assembly.

An object of the invention is to increase the positioning accuracy of a component to a substrate by determination of a component position error during exchange to a component gripper.

By determining position errors of a pickable component, the positioning accuracy of the apparatus may be increased in case of position errors that may occur during picking of a component.

### DESCRIPTION OF THE INVENTION

In a first aspect, a method is provided for determining a positioning error of a pickable component, before the component is placed on a substrate, using an apparatus, wherein the component comprises one or more component marks and an attachment surface, suitable for attaching to the substrate. The component comprises further a gripping surface, arranged opposite to the attachment surface. The apparatus comprises a pick and place actuator arranged to be disposed at a placing position and at a component exchange position. The pick and place actuator comprises a gripper for releasably attaching to the gripping surface of the component. The apparatus comprises a component holder for releasably attaching to the attachment surface of the component and at least one look-up camera arranged to make at least one up-image of at least a portion of the attachment surface of the component. The method comprises the step of attaching the attachment surface of the component to the component holder, the step of moving the component holder with the attached component to the component exchange position, the step of using the at least one look-up camera at the component exchange position to make at least one first up-image of a first component mark, the step of moving the pick and place actuator to the component exchange position, the step of attaching the gripping surface of the component to the gripper and releasing the attaching surface of the component from the component holder, the step of using the at least one look-up camera at the component exchange position to make at least one second up-image of a second component mark, and the step of determining a position error of the component using the at least one second up-image and the at least one first up-image.

By determining position errors using corresponding component marks, the accuracy of the error determination may be increased. This may be advantageous for picking components with less accurate component marks, such as picking chips with rough, irregular edges due to inaccurate sawing. This may be advantageous for flip-chip components.

In an optional aspect of the method, the apparatus comprises at least one look-down camera, arranged to make at least one down-image of at least a portion of the gripping surface of the component, wherein the method comprises the step of using the at least one look-down camera at the component exchange position to make at least one first down-image of a third component mark.

In an optional aspect of the method, the method comprises the step of providing the substrate to the placing position, the step of moving the pick and place actuator to the placing position with the attached component, and the step of placing the component on the substrate at the placing position.

In an optional aspect of the method, the method comprises the step of at least partially correcting the position error of the component by modifying one or more positions and/or orientations selected from the group comprising a rotation of the component, a displacement of the component, a tilt of the component, a rotation of the substrate, a displacement of the substrate, a tilt of the substrate, a rotation of the pick and place actuator, a displacement of the pick and place actuator, a tilt of the pick and place actuator, a rotation of the gripper, a displacement of the gripper, a tilt of the gripper, a rotation of the component holder, a displacement of the component holder, a tilt of the component holder, or any combination thereof.

In an optional aspect of the method, the apparatus comprising a component loading position and the method comprising the step of providing the component to the component loading position, the step of moving the component holder to the component loading position, the step of attaching the component to the component holder and the step of moving the component holder with the attached component to the component exchange position.

In an optional aspect of the method, the substrate comprises at least one substrate mark.

In an optional aspect of the method, the method comprises the step of using the at least one look-down camera at the placing position to make at least one second down-image of a portion of the substrate and/or of at least one substrate mark and the step of determining a fourth position and/or orientation of the substrate using the at least one second down-image.

Similarly, an apparatus is provided for picking a component before the component is placed on a substrate for attachment, wherein the component comprises one or more component marks and an attachment surface, suitable for attaching to the substrate. The component comprises a gripping surface, arranged opposite to the attachment surface. The apparatus comprises a pick and place actuator arranged to be disposed at a placing position and at a component exchange position, which comprises a gripper for releasably attaching to the gripping surface of the component.

The apparatus comprises a component holder for releasably attaching to the attachment surface of the component and at least one look-up camera arranged to make at least one up-image of at least a portion of the attachment surface of the component.

The apparatus is arranged to attach the attachment surface of the component to the component holder and arranged to move the component holder with the attached component to the component exchange position,

The at least one look-up camera is arranged to make at least one first up-image of a first component mark at the component exchange position, and wherein the apparatus is arranged to move the pick and place actuator to the component exchange position;

The apparatus is further arranged to attach the gripping surface of the component to the gripper and arranged to release the attaching surface of the component from the component holder and the at least one look-up camera is arranged to make at least one second up-image of a second component mark at the component exchange position and wherein the apparatus is additionally arranged to determine a position error of the component using the at least one second up-image and the at least one first up-image.

In an optional aspect of the apparatus, the apparatus comprises at least one look-down camera, arranged to make at least one down-image of at least a portion of the gripping surface of the component, wherein the at least one look-down camera is arranged to make at least one first down-image of a third component mark at the component exchange position.

In an optional aspect of the apparatus, the component holder comprises a receiving surface with a component retaining region.

The component retaining region is suitable for receiving and for retaining at least a portion of the attachment surface of the component.

In an optional aspect of the apparatus, the component holder comprises a posterior surface arranged as an opposite surface to the receiving surface, one or more radiation windows, arranged to allow an illumination radiation to pass between the receiving surface and the posterior surface, wherein the at-least one look-up camera is arranged to make the at least one first up-image and/or the at least one second up-image using illumination radiation passing between the receiving surface and the posterior surface.

In an optional aspect of the apparatus, the one or more radiation windows comprise one or more openings and/or one or more regions at least partially transparent to illumination radiation.

In an optional aspect of the apparatus, the one or more radiation windows are at least partially arranged in the component retaining region.

In an optional aspect of the apparatus, the at least one component mark is selected from the group comprising: one or more physical features of at least a portion of a component, one or more optical characteristics of at least a portion of a component, at least a portion of a fiducial on the component, or any combination thereof.

In an optional aspect of the apparatus, the at least one look-down camera is arranged to make at least one second down-image of the at least one substrate mark at the placing position and the apparatus is arranged to determine a fourth position and/or orientation of the substrate using the at least one second down-image.

In an optional aspect of the apparatus, the at least one look-down camera and/or at least one look-up camera are arranged to illuminate at least a portion of a surface of the component.

In an optional aspect of the apparatus, the apparatus comprises a component loading position, wherein the apparatus is arranged to provide the component to the component loading position, to move the component holder to the component loading position to attach the component to the component holder and to move the component holder with the attached component to the component exchange position.

In an optional aspect of the apparatus, the substrate comprises at least one substrate mark.

In an optional aspect of the apparatus and the method, the at least one substrate mark is selected from the group comprising one or more physical features of at least a portion of a substrate, one or more optical characteristics of at least a portion of a substrate, at least a portion of a fiducial on a substrate, or any combination thereof.

In an optional aspect of the apparatus, the at least one look-down camera is arranged to make at least one second down-image of the at least one substrate mark at the placing position and the apparatus is arranged to determine a fourth position and/or orientation of the substrate using the at least one second down-image.

In an optional aspect of the apparatus and method, wherein the component is selected from the group comprising one or more dies, one or more semiconductor packages, one or more chips, one or more flip chips, one or more integrated circuits, one or more further substrates, one or more optical elements, one or more electronic elements, one or more electro-optical elements, or any combination thereof.

In an optional aspect of the apparatus, the apparatus additionally comprises at least one look-down camera, arranged to make at least one down-image of at least a portion of the gripping surface of the component.

In an optional aspect of the apparatus, the at least one look-down camera is additionally arranged to make at least one first down-image of a first component mark at the component exchange position.

In an optional aspect of the apparatus, the at least one look-up camera is arranged to make at least one second up-image of a third component mark at the component exchange position, wherein the apparatus is arranged to determine a position error of the component using the at least one second up-image and the at least one first up-image.

In an optional aspect of the apparatus and the method, the first component mark and the second component mark are physically different, physically similar, physically the same, physically identical, optically different, optically similar, optically the same, optically identical, or any combination thereof.

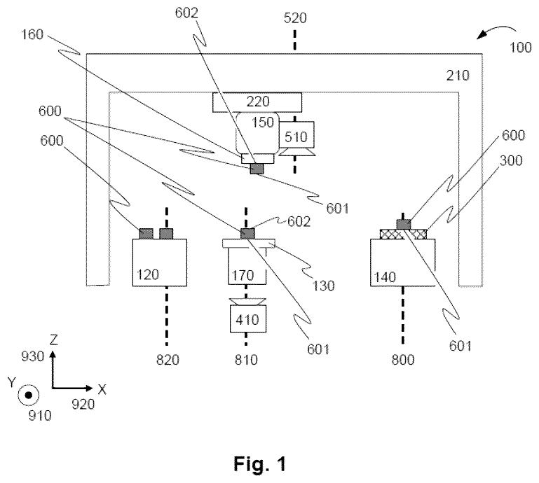

Further advantages and characteristics result from the figures, including FIG. 1, which depicts a schematic cross-section, viewed from a side, of the relevant parts of an apparatus for picking one or more components and for placing the one or more components on one or more substrates for attachment.

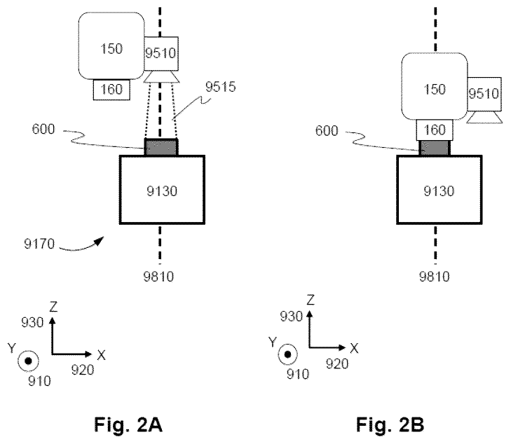

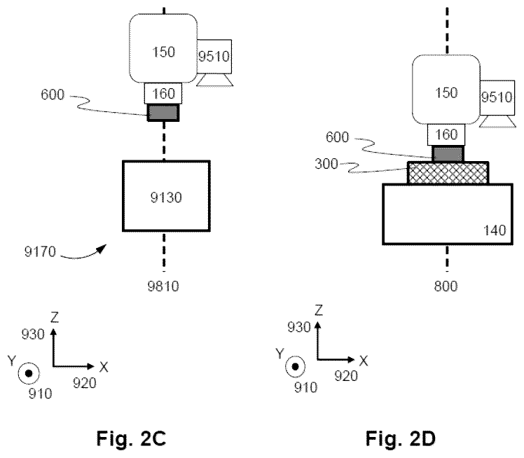

Further advantages and characteristics result from the figures, including FIG. 2A to FIG. 2D, which depict selected steps in a method for picking a component and placing the component on a substrate.

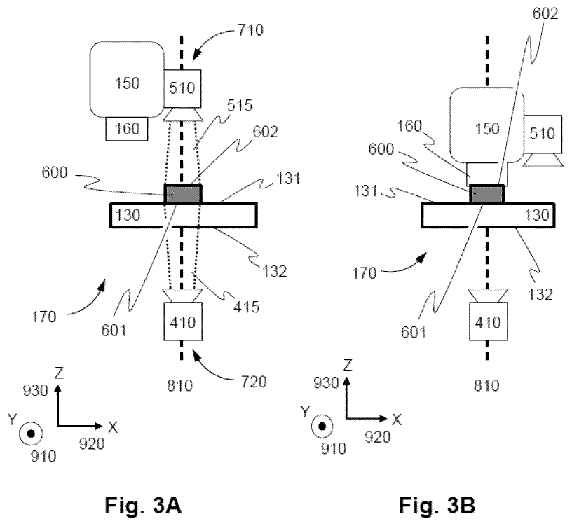

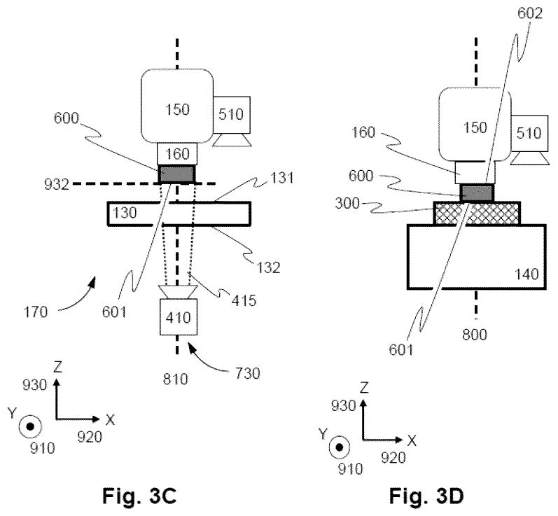

Further advantages and characteristics result from the figures, including FIG. 3A to FIG. 3D, which depict selected steps in an improved method for picking a component and placing the component on a substrate for attachment.

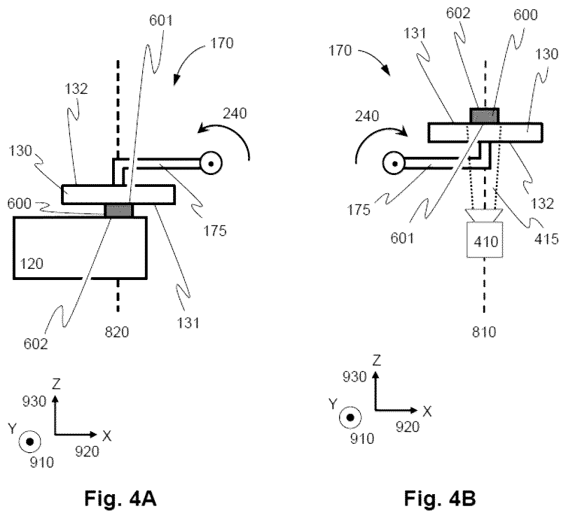

Further advantages and characteristics result from the figures, including FIG. 4A to FIG. 4B, which depict aspects of an improved apparatus for picking a component before placing the component on a substrate for attachment.

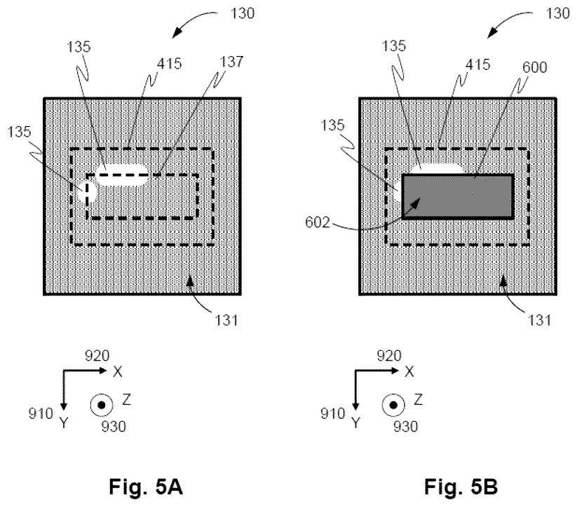

Further advantages and characteristics result from the figures, including FIG. 5A to FIG. 5B, which depict aspects of an improved component holder for releasably attaching to a component.

### DETAILED DESCRIPTION OF THE FIGURES

In the figures, a first axis 910, a second axis 920 and a third 930 axis are depicted to make it easier for a skilled person to relate the different views and different parts together. The first axis 910 is perpendicular to the second axis 920, and the third axis 930 is perpendicular to both the first axis 910 and the second axis 920. It has been assumed that, during use, the first axis 910 is in an Y direction, the second axis 920 is in an X direction and the third axis 930 is in a Z direction. Conventionally, in use, the Y-axis 910 and X-axis 920 are substantially horizontal, horizontal or approximately horizontal. Functionally, the X-axis 920 and Y-axis 910 may be interchanged. Conventionally, in use, the Z-axis 930 is substantially vertical, vertical or approximately vertical. To clarify the description of the different components, the figures depict parts in these orientations. To clarify the description of the different components, some relative terms have been used, such as up, down, upper, side and base to match this convention.

The apparatus described in this disclosure may be arranged by a skilled person to operate at different deviations from the orientations and nominal coordinate axes.

FIG. 1 depicts a schematic cross-section, viewed from a side, of relevant parts of an apparatus 100 suitable for picking one or more components 600 at a component exchange position 810 before the one or more components 600 are placed on one or more substrate 300 according to any of the methods disclosed herein. In the example depicted in FIG. 1, the apparatus 100 is suitable for placing the one or more components 600 on one or more substrates 300 for attachment at a component placing position 800 according to any of the methods disclosed herein. More particularly, the apparatus 100 is viewed when looking towards a plane comprising the X-axis 920, nominally indicated as having a positive direction from left to right, and the Z-axis 930, nominally indicated as having a positive direction from bottom to top. The Y-axis 910 is nominally depicted as having a positive direction out of the drawing, towards the viewer.

For example, the apparatus 100 may be a component (or die) pick and placement system. For example, the apparatus 100 may be a component (or die) bonding apparatus. Typically, dies are rectangular in shape, but round shapes are also possible.

It may be advantageous to arrange the apparatus to place the one or more components 600 on the one or more substrates 300 with a precision in the micrometer range or sub-micrometer range.

As described below, the apparatus 100 is arranged to determine one or more position errors to monitor and optionally reduce alignment errors between a component after placement on a substrate. In general, an actual and/or predicted degree of misalignment may be corrected using any suitable means to provide at least a small degree of movement in one or more directions of a component and/or a substrate. One or more of these corrections may be provided at any convenient moment, such as during a loading, during an unloading, during a transfer between stations, during an initial stage of placing a component on a substrate and/or after placing a component on a substrate. The one or more corrections may be implemented, in practice using movements approximately linearly along one or more axes 910, 920, 930 and/or approximately rotationally around one or more axes 910, 920, 930. Differences in orientation may also be described as differences in tilt.

The methods and apparatus described herein for picking one or more components 600 is not limited to dies-the one or more components 600 may be selected from the group comprising: one or more dies, one or more semiconductor packages, one or more chips, one or more flip chips, one or more integrated circuits, one or more further substrates 300, one or more optical elements, one or more electronic elements, one or more electro-optical elements, or any combination thereof. For example, one component 600 may be placed on one substrate 300, one or more components 600 may be placed on one substrate 300, one component 600 may be placed on one or more substrates 300.

The one or more components 600 comprise one or more component marks, detectable optically by, for example, one or more inspection cameras, and arranged to assist in determining one or more positions and/or orientations of the one or more components 600. The one or more components 600 comprise an attachment surface 601, suitable for attaching to the one or more substrates 300, and comprise an opposite gripping surface, suitable for attaching to a gripper 160.

Optionally, the component exchange position 810 may comprise one or more exchange position marks.

Optionally, the one or more substrates 300 may comprise at least one substrate mark (or substrate alignment target), detectable by one or more inspection cameras, and arranged to assist in determining one or more positions and/or orientations of the one or more substrates 300. The at least one substrate mark may be any suitable alignment target. For example, a substrate mark may be selected from the group comprising: one or more physical features of at least a portion of a substrate 300, one or more optical characteristics of at least a portion of a substrate 300, at least a portion of a fiducial on a substrate, or any combination thereof.

Optionally, the placing position 800 may comprise one or more placing position marks or one or more nominal substrate location marks.

The one or more substrates 300 may be any object having at least one attachable face at a placing position, the attachable face of the one or more substrates 300 being suitable to receive the attachment surface 601 of the one or more components 600. For example, the one or more substrates 300 may be selected from the group comprising: one or more metallic substrates, one or more substrate strips, one or more lead frames, one or more wafers, one or more further components 600, or any combination thereof. The one or more substrates 300 may also be described as one or more media.

FIG. 1 depicts the apparatus 100 comprising a pick and place actuator 150, an optional component feeder (or feeding unit) 120 for providing the one or more components 600, and an optional substrate feeder (or feeding unit) 140 for providing the one or more substrates 300. The optional component feeder 120 is positioned at a component loading position (loading position) 820, and may comprise an optional component handling system, such as a wafer, a tray, a waffle pack or a tape. A component exchanger 170 is arranged (not depicted in FIG. 1) to retain one or more components in a holder (not depicted), and to move one or more retained components 600 to a component exchange position 810. The substrate feeder 140 is positioned at a component placing position (placing position) 800.

Alternatively, the apparatus may be configured as a bonding system, comprising a bond head instead of a pick and place actuator.

FIG. 1 depicts an example of a pick and place drive, comprising a first drive system 210 and a second drive system 220 for the pick and place actuator The second drive system 220 is attached to the first drive system 210 in any suitable way. Any suitable drive configuration may be included in the apparatus 100. For example, the first drive system 210 may be arranged to move the pick and place actuator 150 positively and negatively along the X-axis 920, and the second drive system 220 may be arranged to move the pick and place actuator 150 positively and negatively along the Y-axis 910, whereby the pick and place actuator 150 may be moved between the component exchange position 810 and the component placing position 800.

As depicted in FIG. 1, the apparatus includes at least one look-up (or uplooking) camera 410 and optionally includes at least one look-down (or downlooking) camera 510. In the context of this disclosure, a camera is an optical system arranged to capture an image. In the context of this disclosure, look-up means that the camera is approximately pointed in the positive direction of the Z-axis 930. In the context of this disclosure, look-down means that the camera is approximately pointed in the negative direction of the Z-axis 930.

The at least one look-up camera 410 is arranged to make at least one up-image of one or more components 600. In the example depicted in FIG. 1, the at least one look-up camera 410 is arranged to make at least one up-image of a surface of a component 600 at the component exchange position 810. Optionally, the at least one look-up camera 410 may comprise an illumination source, suitable for illuminating a portion of a surface of a component 600. Additionally or alternatively, one or more illumination sources may be provided which are not comprised in the at least one look-up camera 410. It may also be advantageous for the at least one look-up camera 410 to comprise a direct illumination source, and provide optional indirect illumination using one or more illumination sources not comprised in the at least one look-up camera 410.

The optional at least one look-down camera 510 may be arranged to make at least one down-image of one or more components 600. In the example depicted in FIG. 1, the at least one look-down camera 510 is arranged to make at least one down-image of a surface of a component 600 at the component exchange position 810.

Optionally, the at least one look-down camera 510 may comprise an illumination source, suitable for illuminating a portion of a surface of a component 600. Additionally or alternatively, one or more illumination sources may be provided which are not comprised in the at least one look-down camera 510. It may also be advantageous the at least one look-down camera 510 to comprise a direct illumination source, and to provide optional indirect illumination using one or more illumination sources not comprised in the at least one look-down camera 510.

Optionally, the at least one look-down camera 510 is arranged to make at least one down-image of a surface of a substrate 300 at the component placing position 800.

Each camera 410, 510 comprises one or more image sensors (not depicted), and one or more optical elements (not depicted). The one or more image sensors may use any suitable optical detection technique, such as CMOS. Where necessary, beam paths may be deflected using one of more suitably-configured deflecting mirrors (not depicted).

In the example depicted in FIG. 1, the at least one look-down camera 510 is attached to the pick and place actuator 150.

As depicted in FIG. 1, the pick and place actuator 150 comprises a component gripper 160, arranged to releasably attach to the gripper surface 602 of a component 600 during use, and to retain the attachment during movements of the pick and place actuator 150 and/or the gripper 160. The gripper 160 is, for example, vacuum-operated whereby a degree of suction may be used to retain a component 600 in the gripper 160. The gripper 160 is arranged to be rotatable about the Z-axis 930.

In the example depicted in FIG. 1, the apparatus 100 is arranged to provide at least a portion of a placing process at the placing position 800. During the at least a portion of the placing process, the attachment surface 601 of the one or more components 600 are brought in contact with the one or more substrates 300, allowing one or more placing operations to be performed on at a least a portion of the attachment surface 601. The attachment surface 601 is typically at least a portion of a mutual region of contact between a component and a substrate.

In the example depicted in FIG. 1, the first drive system 210 is arranged to transport the pick and place actuator 150 over relatively long distances, namely from the component exchange position 810, where the pick and place actuator 150 and gripper 160 receive a component 600 from the component exchanger 170, to the placing position 800, where the pick and place actuator 150 and gripper 160 place the component 600 on a substrate 300. The requirements for the position accuracy of the first drive system 210 may be relatively modest, a position accuracy of +/−2 μm is usually sufficient. In the example depicted in FIG. 1, the first drive system 210 is designed as a so-called “gantry” with two or more mechanically highly stable axes of motion, of which two axes of motion allow movements of the pick and place actuator 150 along two axes 910, 920, running perpendicular to each other.

Typically, movements of the pick and place actuator 150 along the Z-axis 930 are required to remove a component 600 from the component exchanger unit 170, and also to place the component 600 in an intended placing position on a substrate 300. This movement along the Z-axis 930 may be performed in many different ways, such as providing the first drive system 210 with a third, stable or highly stable axis of motion arranged to provide movement along the Z-axis 930 of the pick and place actuator. Additionally or alternatively, the second drive system 220 may be provided with an additional, high-precision drive arranged to provide movements of the pick and place actuator 150 along the Z-axis 930. Additionally or alternatively, the pick and place actuator 150 may comprise a high-precision drive arranged to provide movements of the gripper 160 along the Z-axis 930. The apparatus 100 may comprise only one, or two or all three of the above axes of motion/drives for the movements along the Z-axis 930.

In the example depicted in FIG. 1, the second drive system 220 is arranged to move the pick and place actuator 150 between processing positions, and also to enable high-precision correction movements of the pick and place actuator 150 in two different directions 910, 920.

In the example depicted in FIG. 1, the pick and place actuator 150 optionally comprises a drive for the rotation of the component gripper 160 around the Z-axis 930.

Additionally or alternatively, the component exchanger 170 may be arranged to rotate one or more components 600 about the Z-axis 930 to reduce or eliminate at least a degree of angular error.

Additionally or alternatively, the substrate feeder 140 may be arranged to rotate one or more substrates 300 about the Z-axis 930 to reduce or eliminate at least a degree of angular error.

In the example depicted in FIG. 1, the range of motion of the second drive system 220 is typically small or very small compared to the range of motion of the first drive system 210. The second drive system 220 is arranged to move the pick and place actuator 150 to one or more processing positions, and arranged to provide high-precision correction movements of the pick and place actuator 150 in two different directions 910, 920.

The one or more components 600 comprise a first surface, nominally described as the top surface using the orientations depicted in FIG. 1. The first surface is suitable for being releasably attached to the gripper 160, and is therefore also described as a gripper surface 602. The one or more components 600 comprise a second surface, nominally described as the bottom surface using the orientations depicted in FIG. 1. The second surface is suitable for being attached to a substrate, and is therefore also described as an attachment surface 601. The second surface is suitable for being releasably attached to the component holder 130.

The apparatus 100 is arranged at the component exchanging position 810 to move a component 600, attached to the gripper 160, along the Z-axis 930 away from the holder 130.

The apparatus 100 described above in relation to FIG. 1, and all the variations and embodiments described herein, are suitable for performing the improved methods disclosed herein.

FIG. 2A to FIG. 2D depict selected steps from a method for picking a component and placing the component on a substrate. The apparatus depicted in FIG. 1 may be modified to perform the method using modified components and modules. The modified components and modules depicted in FIG. 2A to 2D with the same reference numbers function in a similar way as the corresponding components and modules in FIG. 1, but are not identical. The modules and components in FIG. 2A to 2D are shown in a schematic cross-section, viewed from a side, during picking and placing. More particularly, the components and modules are viewed when looking towards a plane comprising the X-axis 920, nominally indicated as having a positive direction from left to right, and the Z-axis 930, nominally indicated as having a positive direction from bottom to top. The Y-axis 910 is nominally depicted as having a positive direction out of the drawing, towards the viewer.

As depicted in FIG. 2A, a component exchanger 9170 retains a component 600 on a component holder 9130 at a component exchange position 9810. At the component exchange position 9810, a look-down camera 9510 is used to make an image of the component 600 positioned within the field-of-view 9515 of the look-down camera 9510. The image is subsequently used to determine a position of the component 600.

After making the image, the pick and place actuator 150 is moved to the component exchange position 9810.

As depicted in FIG. 2B, the pick and place actuator 150 is positioned such that the gripper 160 is facing the component 600 and such that the gripper 160 is in the proximity of the component 600. As depicted in FIG. 2B, the pick and place actuator 150 attaches to the component 600 at the component exchange position 9810.

After attaching the gripper 160 to the component 600, the component holder 9130 releases the component 600.

As depicted in FIG. 2C, the pick and place actuator 150 is moved away from the component holder 9130, while the component 600 is retained by the gripper 160, whereby a clearance is created for further movement of the component 600 to the placing position 800.

After creating sufficient clearance, the pick and place actuator 150 and the component 600 are moved to the component placing position 800.

As depicted in FIG. 2D, the apparatus 100 provides a substrate 300 to the component placing position 800. As depicted in FIG. 2D, the pick and place actuator 150 is moved such that the component 600 is proximate the substrate 300. As depicted in FIG. 2D, the component 600 is placed by the gripper 160 releasing the component 600 at the placing position 800.

A disadvantage of the picking method is that any significant displacement errors made when the component 600 is attached to the gripper 160 are not detected or measured during the picking steps. For example, significant displacement errors may be up to a few microns. For example, significant displacement errors may be up to five microns (μm). This often results in an unrecognized alignment error between the component 600 and the substrate 300 at the component placing position 800. In other words, before placing, there may be an unrecognized position and/or orientation error between the component 600 and the substrate 300 at the component placing position 800.

In order to reduce the risk of unrecognized alignment errors, improved methods for picking are described herein. These improved methods for alignment may also reduce the extent of any unrecognized alignment errors. For example, the significant displacement errors may be reduced to less than one micron (μm). For example, the significant displacement errors may be reduced to less than 500 nanometer (nm). For example, the significant displacement errors may be reduced to approximately be in the range of 100 nm to 500 nm.

FIG. 3A to FIG. 3D depict selected steps from an improved method. The apparatus depicted in FIG. 1 is suitable for performing the improved method for picking a component 600 and placing the component on a substrate 300. The components and modules depicted in FIG. 3A to FIG. 3D with the same reference numbers function in the same way as the corresponding components and modules in FIG. 1. The modules and components in FIG. 3A to 3D are shown in a schematic cross-section, viewed from a side, during picking and placing. More particularly, the components and modules are viewed when looking towards a plane comprising the X-axis 920, nominally indicated as having a positive direction from left to right, and the Z-axis 930, nominally indicated as having a positive direction from bottom to top. The Y-axis 910 is nominally depicted as having a positive direction out of the drawing, towards the viewer.

As depicted in FIG. 3A, the component exchanger 170 retains a component 600 on a receiving surface 131 of the component holder 130 at the component exchange position 810. The receiving surface 131 of the component holder 130 is suitable for receiving and for retaining at least a portion of the attachment surface 601 of the component 600. In the example depicted in FIG. 3A, the attachment surface 601 of the component 600 is received by the receiving surface 131 of the component holder 130. In the example depicted in FIG. 3A, the component holder 130 comprises a posterior surface 132, arranged as an opposite surface to the receiving surface 131.

In the example depicted in FIG. 3A, the at least one look-down camera 510 is arranged to make at least one down-image of at least a portion of the gripping surface 602 of the component 600 at the component exchange position 810. In the example depicted in FIG. 3A, the at least one look-down camera 510 is used to make at least one first down-image 710 of a first component mark comprised in the component 600. The at least one first down-image 710 may optionally be used to determine a position error of the component 600. The at least one first down-image 710 may optionally be used to determine a first position and/or orientation of the component 600.

In the example depicted in FIG. 3A, the at least one look-up camera 410 is arranged to make at least one up-image of at least a portion of the attachment surface 601 of the component 600 at the component exchange position 810. In the example depicted in FIG. 3A, the at least one look-up camera 410 is used to make at least one first up-image 720 of a second component mark comprised in the component. The at least one first up-image 720 is subsequently used to determine a position error of the component 600. The at least one first up-image 720 may optionally be used to determine a second position and/or orientation of the component 600.

Any suitable component mark may be used. For example, one or more marks selected from the group comprising: one or more physical features of at least a portion of the component 600, one or more optical characteristics of at least a portion of the component 600, at least a portion of a fiducial on a component, or any combination thereof. Physical features may include, for example, one or more edges, one or more corners, one or more facets. A second component mark may comprise, for example, at least a portion of an edge, such as a sawing edge. Component marks may be physically different, physically similar, physically the same, physically identical, optically different, optically similar, optically the same, optically identical, or any combination thereof. For example, the same physical component mark may be considered as more different component marks if it is viewed under one or more different optical arrangements and/or orientations.

It may be advantageous if a second component mark and a third component mark comprises at least a portion of an active die structure comprised in the gripper surface 602 of a component because of a higher accuracy, which may be achieved.

In the example depicted in FIG. 3A, the component exchanger 170 is arranged such that the at least one look-down camera 510 faces the receiving surface 131 of the component holder 130.

In the example depicted in FIG. 3A, the component exchanger 170 is arranged such that the at least one look-down camera 510 faces the gripper surface 602 of the component 600, whereby one or more down-images are made of one or more first component marks.

In the example depicted in FIG. 3A, the component exchanger 170 is arranged such that the at least one look-up camera 410 faces the posterior surface 132 of the component holder 130.

In the example depicted in FIG. 3A, the component holder 130 is arranged such that the at least one look-up camera 410 faces at least a portion of the attachment surface 601 of the component 600, whereby one or more up-images are made of one or more second component marks.

For example, one or more radiation windows (not depicted) may be provided in the component holder 130 and arranged to allow an illumination radiation to pass between the receiving surface 131 and the posterior surface 132 of the component holder.

For example, a component holder may be a transparent plate, such as a glass plate, with vacuum holes, providing relatively large radiation windows. This may be advantageous because it allows a degree of simultaneous surface inspection.

For example, the one or more radiation windows may be located at one or more corners of a component. For example, the one or more radiation windows may be located approximately in a centre of one or more sides of a component.

After making the at least one first down-image 710 and making the at least one first up-image 720, the apparatus moves the pick and place actuator 150 to the component exchange position 810. Optionally, predetermined relative positions and/or orientations between the pick and place actuator 150 and the look-down camera 510 may be used to influence the accuracy of the movement. Additionally or alternatively, the at least one first down-image 710 may be used to determine a first position and/or orientation of the component 600 to influence the accuracy of the movement.

As depicted in FIG. 3B, the pick and place actuator 150 is positioned such that the gripper 160 is facing the gripper surface 602 of the component 600 and such that the gripper 160 is proximate the gripper surface 602 of the component 600. As depicted in FIG. 3B, the gripper 160 is attached to the gripper surface 602 of the component 600 at the component exchange position 810.

After attaching the gripper 160 to the gripper surface 602 of the component 600, the receiving surface 131 of the component holder 130 releases the attachment surface 601 of the component 600.

As depicted in FIG. 3C, the pick and place actuator 150 is moved away from the component holder 130 along the Z-axis 930 away from the receiving surface 131 of the component holder 130 while the component 600 is retained by the gripper 160. After being released by the component holder 130 and movement along the Z-axis 930, the component 600 is positioned at a further inspection position 932. In the example depicted in FIG. 3C, the attachment surface 601 of the component 600 is positioned at a further inspection position 932. In the example depicted in FIG. 3C, the attachment surface 601 of the component 600 is maintained in a field-of-view 415 of the at least one look-up camera 410. In the example depicted in FIG. 3C, a position of close proximity between the attachment surface 601 of the component 600 and the receiving surface 131 of the holder 130 is maintained while at least one second up-image 730 is made. In the context of this disclosure, close proximity means that the average separation between the attachment surface 601 of the component 600 and the receiving surface 131 of the holder 130 may be in the range 10 to 200 μm.

At the component exchange position 810, the look-up camera 410 is used to make at least one second up-image 730 of the third component mark at the further inspection position 932.

It may be advantageous to arrange the further inspection position 932 of the component 600 such that the attachment surface 601 of the component 600 is maintained in an optimal imaging range of the look-up camera 410, such as in a depth-of-focus arranged to make the at least one first up-image 720 depicted in FIG. 3A and the at least one second up-image 730 depicted in FIG. 3C. This may provide a higher degree in accuracy because differences in the optical paths and optical configurations are reduced if comparing positions and/orientations of the third component mark with positions and/orientations of the second component mark. Additionally or alternatively, a focus of the look-up camera 410 may be modified to capture the at least one third images 730 in an optimal imaging range. Optionally, the third component mark and the second component mark may share one or more of the same physical features of a component, such as one or more edges. Additionally or alternatively, the third component mark and the second component mark may share one or more of the same optical characteristics of the component. Additionally or alternatively, the third component mark and the second component mark may be comprised in the same surface of a component. Additionally or alternatively, the third component mark and/or the second component mark may be comprised in the attachment surface 601 of the component 600.

The at least one second up-image 730 is used and the at least one first up-image 720 to determine a position error of the component 600. For example, a second position and/or orientation of the component 600 may be determined using the at least one first up-image 720. For example, a third position and/or orientation of the component 600 may be determined using the at least one second up-image 730. For example, the position error of the component 600 may be determined using the third position and/or orientation with the second position and/or orientation. The position error of the component 600 corresponds to a difference between the second component position (attached to the component holder 130) and third component position (attached to gripper 160 after being released from the component holder 130) caused by a component shift during release from the component holder 130.

Additionally or alternatively, the position error of the component 600 determined after the step depicted in FIG. 3C may be at least partially corrected before placing the component 600 on the substrate 300 at the component placing position 800.

Optionally, the at least partial correction may be retained for one or more subsequent components. For example, the position error of the component 600 may be at least partially corrected by modifying one or more suitable positions and/or orientations selected from the group comprising: a rotation of the component 600, a displacement of the component 600, a tilt of the component 600, a rotation of the substrate 300, a displacement of the substrate 300, a tilt of the substrate 300, a rotation of the pick and place actuator 150, a displacement of the pick and place actuator 150, a tilt of the pick and place actuator 150, a rotation of the gripper 160, a displacement of the gripper 160, a tilt of the gripper 160, or any combination thereof. Additionally or alternatively, an expected position error of a subsequent component may be at least partially corrected by modifying one or more suitable positions and/or orientations selected from the group comprising: a rotation of the component holder 130, a displacement of the component holder 130, a tilt of the component holder 130, or any combination thereof.

Optionally, if a clearance for further movement is too small after the step depicted in FIG. 3C, the apparatus moves the pick and place actuator 150 further away from the component holder 130 while the component 600 is retained by the gripper 160. After creating sufficient clearance, the pick and place actuator 150 and the component 600 are moved by the apparatus to the component placing position 800.

As depicted in FIG. 3D, the apparatus 100 provides a substrate 300 to the placing position 800. As depicted in FIG. 3D, the apparatus moves the pick and place actuator 150 such that the attachment surface 601 of the component 600 is proximate the substrate 300 and/or to the component placing position 800, optionally correcting at least partially for one or more position errors of the component 600. As depicted in FIG. 3D, the apparatus 100 then places the attachment surface 601 of the component 600 on the substrate 300 by the gripper 160 releasing the gripper surface 602 of the component 600 at the component placing position 800.

In the example depicted in FIG. 4A and FIG. 4B, aspects of an improved apparatus as depicted in FIG. 1 are shown. The components and modules depicted in FIG. 4A and FIG. 4B with the same reference numbers function in the same way as the corresponding components and modules in FIG. 1 and FIG. 3A to FIG. 3D. In the example depicted in FIG. 4A to FIG. 4B, optional method steps are also depicted which may be performed before the step depicted above in FIG. 3A to provide a component 600 retained on a receiving surface 131 of the component holder 130 at the component exchange position 810. The components and modules in FIG. 4A to 4B are shown in a schematic cross-section, viewed from a side, during component loading and before component exchange. More particularly, the components and modules are viewed when looking towards a plane comprising the X-axis 920, nominally indicated as having a positive direction from left to right, and the Z-axis 930, nominally indicated as having a positive direction from bottom to top. The Y-axis 910 is nominally depicted as having a positive direction out of the drawing, towards the viewer.

As depicted in FIG. 4A, the component exchanger 170 is arranged to receive a component 600 at the component loading position 820 from an optional component feeder 120, and arranged to retain the component 600 on the component holder 130.

As depicted in FIG. 4B, the component exchanger 170 is arranged to retain the component 600 on the component holder 130 at the component exchange position 810, and arranged to release the component 600 to the pick and place actuator (not depicted). Optionally, the component feeder 120 may be arranged to retain and release the component. Any suitable component exchanger 170 may be used in the apparatus depicted in FIG. 1.

In the example depicted in FIG. 4A and FIG. 4B, a flip-unit type of component exchanger 170 may be provided, comprising a component holder 130, comprising a means (not depicted) for exchanger rotation 240 in both directions around the first axis (Y-axis) 910 and comprising an exchanger member 175 connecting the component holder 130 to the means for exchanger rotation (not depicted). In the example depicted in FIG. 4A and FIG. 4B, the component exchanger 170 is arranged to rotate 240 over an approximate half-circle, clockwise and anti-clockwise, between the component loading position 820, depicted in FIG. 4A, and the component exchange position 810, depicted in FIG. 4B.

In the example depicted in FIG. 4A, the component exchanger 170 has been rotated 240 anti-clockwise around the first axis (Y) 910, the receiving surface 131 of the component holder 130 has been moved proximate to the attachment surface 601 of the component 600, and the attachment surface 601 of the component 600 has been attached to the receiving surface 131 of the component holder 130.

After receiving the component 600 at the component loading position 820, the component exchanger 170 rotates clockwise around the first axis (Y) 910 to the component exchange position 810.

In the example depicted in FIG. 4B, the component exchanger 170 retains the component 600 on the receiving surface 131 of the component holder 130 at the component exchange position 810. In the example depicted in FIG. 4B, the component exchanger 170 is arranged such that the at least one look-up camera 410 faces the posterior surface 132 of the component holder 130. In the example depicted in FIG. 4B, the attachment surface 601 of the component 600 is maintained in a field-of-view 415 of the at least one look-up camera 410. In the example depicted in FIG. 4B, the at least one look-up camera 410 faces at least a portion of the attachment surface 601 of the component 600, whereby one or more up-images are made of one or more second component marks. In the example depicted in FIG. 4B, one or more radiation windows (not depicted) are provided in the component holder 130 and arranged to allow an illumination radiation to pass between the receiving surface 131 and the posterior surface 132 of the component holder 130.

After retaining the component 600 on the receiving surface 131 of the component holder 130 at the component exchange position 810, the component exchanger 170 depicted in FIG. 4B is suitable for performing the steps of the improved methods depicted in FIG. 3A to 3D and described above. In particular, the component exchanger 170 depicted in FIG. 4A to FIG. 4B is suitable for performing the step depicted in FIG. 3C, wherein the attachment surface 601 of the component 600 is maintained at the further inspection position (not depicted) while at least one second up-image (not depicted) is made. The component exchanger 170 depicted in FIG. 4A to FIG. 4B is suitable for performing the step depicted in FIG. 3C, wherein the attachment surface 601 of the component 600 is maintained in a field-of-view 415 of the at least one look-up camera 410.

FIG. 5A and FIG. 5B, depict aspects of an improved component holder 130 for releasably attaching to a component. The example depicted in FIGS. 5A and 5B is suitable for use in the component exchanger 170 depicted in FIG. 3A to FIG. 3D. The components and modules depicted in FIG. 5A and FIG. 5B with the same reference numbers function in the same way as the corresponding components and modules in FIG. 1, FIG. 3A to FIG. 3D, and FIG. 4A and FIG. 4B. The example depicted in FIGS. 5A and 5B is suitable for use in the component exchanger 170 depicted in FIG. 4A and FIG. 4B. The modules and components in FIG. 5A and FIG. 5B are shown in a schematic plan view, viewed from above, looking down. More particularly, the components and modules are viewed when looking towards a plane comprising the X-axis 920, nominally indicated as having a positive direction from left to right, and the Y-axis 910, nominally indicated as having a positive direction from top to bottom. The Z-axis 930 is nominally depicted as having a positive direction out of the drawing, towards the viewer.

In the example depicted in FIG. 5A, the attachment surface 131 of the component holder 130 is depicted in the plane of the drawing without a component (not depicted). In the example depicted in FIG. 5A, the extent of a component retaining region 137 is indicated, providing a nominal position for receiving a component (not depicted) and releasably attaching to a component (not depicted), whereas the extent of the component retaining region 137 is predetermined and/or controlled to correspond to the expected dimensions and orientations of components (not depicted) to be received. In the example depicted in FIG. 5A, the component holder 130 further comprises one or more radiation windows 135, which are arranged to allow an illumination radiation to pass between the receiving surface 131 and the posterior surface (not depicted) of the component holder 130. In the example depicted in FIG. 5A, the one or more radiation windows 135 are at least partially arranged in the component retaining region 137. In the example depicted in FIG. 5A, the one or more radiation windows 135 are provided proximate to a position where it is predicted that a corner of a component (not depicted) will be positioned during use. In the example depicted in FIG. 5A, the one or more radiation windows 135 are provided at positions where it is predicted that an edge of a component (not depicted) will be positioned during use.

In the example depicted in FIG. 5A, the at least one look-up camera (not depicted) is positioned directly behind the component holder 130, whereas the extent of a field-of-view 415 of the at least one look-up camera (not depicted) is also indicated. In the example depicted in FIG. 5A the one or more radiation windows 135 are at least partially arranged in the field-of-view 415 of the at least one look-up camera (not depicted). In the example depicted in FIG. 5A, the one or more radiation windows 135 are substantially arranged in the field-of-view 415 of the at least one look-up camera (not depicted). In the example depicted in FIG. 5A, the one or more radiation windows 135 are completely arranged in the field-of-view 415 of the at least one look-up camera (not depicted). In the example depicted in FIG. 5A, the extent of the component retaining region 137 is at least partially arranged in the field-of-view 415 of the at least one look-up camera (not depicted). In the example depicted in FIG. 5A, the extent of the component retaining region 137 is substantially arranged in the field-of-view 415 of the at least one look-up camera (not depicted). In the example depicted in FIG. 5A, the field-of-view 415 of the at least one look-up camera (not depicted) is arranged symmetrically around the extent of the component retaining region 137. In the example depicted in FIG. 5A, the extent of the component retaining region 137 is completely arranged in the field-of-view 415 of the at least one look-up camera (not depicted). In the example depicted in FIG. 5A, the field-of-view 415 of the at least one look-up camera (not depicted) is arranged to enclose at least a portion of the component retaining region 137.

The example depicted in FIG. 5B is the same as the example depicted in FIG. 5A, except for the following five differences:
difference 1: a component 600 is depicted, retained on the attachment surface 131;
difference 2: the component 600 is depicted retained in the component retaining region (not depicted);
difference 3: the component 600 is depicted with the negative Y/negative X corner proximate to the one more radiation windows 135;
difference 4: the component 600 is depicted with a portion of the negative X edge in the one more radiation windows 135; and
difference 5: the component 600 is depicted with a portion of the negative Y edge in the one more radiation windows 135.

Optionally, the component holder 130 may comprise means for releasing and/or retaining a component, such as channels and a vacuum supply.

Optionally, the component holder 130 may be arranged for one or more component dimensions and/or one or more component orientations.

Optionally, the one or more radiation windows 135 may be arranged symmetrically within the component retaining region 137.

Optionally, the one or more radiation windows 135 may comprise one or more openings.

Optionally, the one or more radiation windows 135 may comprise one or more regions at least partially transparent to illumination radiation, such as glass or plastic windows in a metal component holder 130. For example, one or more radiation windows may be provided in opaque material.

Optionally, the field-of-view 415 of the at least one look-up camera (not depicted) may be arranged to enclose a portion of the component retaining region 137.

Optionally, the field-of-view 415 of the at least one look-up camera (not depicted) may be arranged asymmetrically around the extent of the component retaining region 137.

Optionally, at least a portion of the one or more radiation windows 135 may be provided at symmetrical positions in the component retaining region 137.

Optionally, at least a portion of the one or more radiation windows 135 may be provided at asymmetrical positions in the component retaining region 137.

Optionally, the one or more radiation windows 135 may be provided at positions proximate where it is predicted that a plurality of corners of a component (not depicted) will be positioned during use.

Optionally, the one or more radiation windows 135 may be provided at positions where it is predicted that a plurality of edges of a component (not depicted) will be positioned during use.

So, in summary, a method and apparatus are provided for determining a positioning error of a pickable component, the apparatus 100 comprising a component holder 130 for releasably attaching to the component 600, the method comprising using a look-up camera 410 at a component exchange position to make a first image 720 of a first component mark, attaching the component to a gripper 160, releasing the component, using the look-up camera to make a second image 730 of a second component mark, and determining a position error using the second image with the first image.

By determining position errors using corresponding component marks, the accuracy of the error determination may be increased. This may be advantageous for picking components with less accurate component marks, such as picking chips with rough, irregular edges due to inaccurate sawing. This may be advantageous for flip-chip components.

Optionally, during one or more steps of the methods described herein, the apparatus may be preconfigured to perform one or more predetermined operations to improve throughput. Additionally or alternatively, the apparatus may be preconfigured to control one or more operations during use.

Many functions and features are described in this disclosure as being comprised in a pick and place actuator, or attached to a pick and place actuator, or associated with a pick and place actuator, but these should be taken as mere examples. A skilled person may configure and arrange one or more of these functions and features to be only partially comprised in a pick and place actuator, or only partially attached to a pick and place actuator, or only partially associated with a pick and place actuator.

In the embodiments described herein, one or more position errors may be determined using one or more images. However, all the embodiments described and disclosed herein can also provide similar advantages by using any convenient form of position recognition and/or detection, such as image analysis, line scanning, or position sensing. Similarly, in the embodiments described herein, one or more images may be made using one or more cameras. However, all the embodiments described and disclosed herein can also provide similar advantages by using any convenient optical system or position recognition device or position detection device, such as a camera, a line-scanner or a position sensitive device (PSD).

For example, one or more look-up cameras may be positioned at an approximately 90-degree angle, with reflectors, such as mirrors, provided to redirect the optical path.

For example, one or more look-down cameras may be positioned with two or more 45-degree reflectors, such as mirrors, to arrange the one or more look-down cameras as one or more look-up cameras.

For example, one or more look-down cameras may be positioned at an approximately 90-degree angle, with reflectors, such as mirrors, provided to redirect the optical path.

For example, one or more look-up cameras may be positioned with two or more 45-degree reflectors, such as mirrors, to arrange the one or more look-up cameras as one or more look-down cameras.

### LIST OF REFERENCES

100 apparatus for picking and placing
120 component feeder or feeding unit
130 component holder
131 receiving surface
132 posterior surface
135 radiation window
137 component-retaining region
140 substrate feeder or feeding unit
150 pick and place actuator
160 component gripper
170 component exchanger
175 exchanger member
210 first drive system
220 second drive system
240 exchanger rotation
300 substrate
410 look-up camera
415 field-of-view of look-up camera
510 look-down camera
515 field-of-view of look-down camera
520 optical axis of a look-down camera
600 component
601 attachment surface
602 gripper surface
710 first down-image
720 first up-image
730 second up-image
800 component placing position
810 component exchange position
820 component loading position
910 first axis (Y)
920 second axis (X)
930 third axis (Z)
932 further inspection position
9130 component holder
9170 component exchanger
9510 look-down camera
9515 field-of-view of look-down camera
9810 component exchange position

1. A method for determining a positioning error of a pickable component (600), before the component (600) is placed on a substrate (300), using an apparatus (100), wherein:
the component (600) comprises one or more component marks; and
the component (600) comprises an attachment surface (601), suitable for attaching to the substrate (300), and comprises a gripping surface (602), arranged opposite to the attachment surface (601);
the apparatus (100) comprising:
a pick and place actuator (150) arranged to be disposed at a placing position (800) and at a component exchange position (810), the pick and place actuator (150) comprising a gripper (160) for releasably attaching to the gripping surface of the component (600);
a component holder (130) for releasably attaching to the attachment surface (601) of the component (600); and
at least one look-up camera (410) arranged to make at least one up-image of at least a portion of the attachment surface (601) of the component;
the method comprising:
attaching the attachment surface (601) of the component (600) to the component holder (130);
moving the component holder (130) with the attached component (600) to the component exchange position (810);
using the at least one look-up camera (410) at the component exchange position (810) to make at least one first up-image (720) of a first component mark;
moving the pick and place actuator (150) to the component exchange position (810);
attaching the gripping surface of the component (600) to the gripper (160) and releasing the attaching surface of the component (600) from the component holder (130);
using the at least one look-up camera (410) at the component exchange position (810) to make at least one second up-image (730) of a second component mark; and
determining a position error of the component (600) using the at least one second up-image (730) and the at least one first up-image (720).

2. The method according to claim 1, wherein the apparatus comprises:
at least one look-down camera (510), arranged to make at least one down-image of at least a portion of the gripping surface (602) of the component (600);
wherein the method comprises:
using the at least one look-down camera (510) at the component exchange position (810) to make at least one first down-image (710) of a third component mark.

3. The method according to claim 1, wherein the method comprises:
providing the substrate (300) to the placing position (800);
moving the pick and place actuator (150) to the placing position (800) with the attached component (600); and
placing the component (600) on the substrate (300) at the placing position (800).

4. The method according to claim 1, wherein the method comprises at least partially correcting the position error of the component (600) by modifying one or more positions and/or orientations selected from the group comprising: a rotation of the component (600), a displacement of the component (600), a tilt of the component (600), a rotation of the substrate (300), a displacement of the substrate (300), a tilt of the substrate (300), a rotation of the pick and place actuator (150), a displacement of the pick and place actuator (150), a tilt of the pick and place actuator (150), a rotation of the gripper (160), a displacement of the gripper (160), a tilt of the gripper (160), a rotation of the component holder (130), a displacement of the component holder (130), a tilt of the component holder (130), or any combination thereof.

5. The method according to claim 1, wherein the apparatus (100) comprises a component loading position (820), the method comprising:
providing the component (600) to the component loading position (820);
moving the component holder (130) to the component loading position (820);
attaching the component (600) to the component holder (130); and
moving the component holder (130) with the attached component (600) to the component exchange position (810).

6. The method according to claim 1, wherein the substrate (300) comprises at least one substrate mark (340).

7. The method according to claim 6, wherein the method comprises:
using the at least one look-down camera (510) at the placing position (800) to make at least one second down-image of a portion of the substrate and/or of at least one substrate mark (340); and
determining a fourth position and/or orientation of the substrate (300) using the at least one second down-image.

8. An apparatus for picking a component (600) before the component (600) is placed on a substrate (300) for attachment, wherein:
the component (600) comprises one or more component marks; and
the component (600) comprises an attachment surface (601), suitable for attaching to the substrate (300), and comprises a gripping surface (602), arranged opposite to the attachment surface (601);
the apparatus (100) comprising:
a pick and place actuator (150) arranged to be disposed at a placing position (800) and at a component exchange position (810), the pick and place actuator (150) comprising a gripper (160) for releasably attaching to the gripping surface of the component (600);
a component holder (130) for releasably attaching to the attachment surface (601) of the component (600); and
at least one look-up camera (410) arranged to make at least one up-image of at least a portion of the attachment surface (601) of the component (600);
wherein the apparatus (100) is arranged to attach the attachment surface (601) of the component (600) to the component holder (130) and arranged to move the component holder (130) with the attached component (600) to the component exchange position (810);
wherein the at least one look-up camera (410) is arranged to make at least one first up-image (720) of a first component mark at the component exchange position (810);
wherein the apparatus (100) is arranged to move the pick and place actuator (150) to the component exchange position (810);
wherein the apparatus (100) is arranged to attach the gripping surface of the component (600) to the gripper (160) and arranged to release the attaching surface of the component (600) from the component holder (130);
wherein the at least one look-up camera (410) is arranged to make at least one second up-image (730) of a second component mark at the component exchange position (810); and
wherein the apparatus (100) is arranged to determine a position error of the component (600) using the at least one second up-image (730) and the at least one first up-image (720).

9. The apparatus according to claim 8, wherein the apparatus (100) comprises:
at least one look-down camera (510), arranged to make at least one down-image of
at least a portion of the gripping surface of the component (600);
wherein the at least one look-down camera (510) is arranged to make at least one first down-image (710) of a third component mark at the component exchange position (810).

10. The apparatus according to claim 8, wherein the component holder (130) comprises:
a receiving surface (131) with a component retaining region (137), the component retaining region (137) being suitable for receiving and for retaining at least a portion of the attachment surface (601) of the component (600);
a posterior surface (132) arranged as an opposite surface to the receiving surface (131);
one or more radiation windows (135), arranged to allow an illumination radiation to pass between the receiving surface (131) and the posterior surface (132);
wherein the at-least one look-up camera (410) is arranged to make the at least one first up-image (720) and/or the at least one second up-image (730) using illumination radiation passing between the receiving surface (131) and the posterior surface (132).

11. The apparatus according to claim 10, wherein the one or more radiation windows (135) comprise one or more openings and/or one or more regions at least partially transparent to illumination radiation.

12. The apparatus according to claim 10, wherein the one or more radiation windows (135) are at least partially arranged in the component retaining region (137).

13. The apparatus according to claim 8, wherein at least one component mark is selected from the group comprising:
one or more physical features of at least a portion of a component (600), one or more optical characteristics of at least a portion of a component (600), at least a portion of a fiducial on the component (600), or any combination thereof.

14. The apparatus according to claim 8, wherein the apparatus (100) is arranged:
to provide the substrate (300) to the placing position (800);
to move the pick and place actuator (150) to the placing position (800) with the attached component (600); and
to place the component (600) on the substrate (300) at the placing position (800).

15. The apparatus according to claim 8, wherein the first component mark and the second component mark share one or more of the same physical features of the component (600) and/or share one or more of the same optical characteristics of the component (600).

16. The apparatus according to claim 8, wherein the at least one look-down camera (510) and/or at least one look-up camera (410) are arranged to illuminate at least a portion of a surface of the component (600).

17. The apparatus according to claim 8, wherein the apparatus (100) comprises a component loading position (820), wherein the apparatus (100) is arranged to provide the component (600) to the component loading position (820), to move the component holder (130) to the component loading position (820) to attach the component (600) to the component holder (130) and to move the component holder (130) with the attached component (600) to the component exchange position (810).

18. The apparatus according to claim 8, wherein the substrate (300) comprises at least one substrate mark (340).

19. The apparatus according to claim 18, wherein the at least one substrate mark (340) is selected from the group comprising:
one or more physical features of at least a portion of a substrate (300), one or more optical characteristics of at least a portion of a substrate (300), at least a portion of a fiducial on a substrate, or any combination thereof.

20. The apparatus according to claim 18, wherein:
the at least one look-down camera (510) is arranged to make at least one second down-image of the at least one substrate mark (340) at the placing position (800); and
the apparatus is arranged to determine a fourth position and/or orientation of the substrate (300) using the at least one second down-image.

21. The apparatus according to claim 8, wherein the component (600) is selected from the group comprising:
one or more dies, one or more semiconductor packages, one or more chips, one or more flip chips, one or more integrated circuits, one or more further substrates (300), one or more optical elements, one or more electronic elements, one or more electro-optical elements, or any combination thereof.

22. The apparatus according to claim 8, additionally comprising at least one look-down camera (510), arranged to make at least one down-image of at least a portion of the gripping surface (602) of the component (600).

23. The apparatus according to claim 8, wherein the at least one look-down camera (510) is additionally arranged to make at least one first down-image (710) of a first component mark at the component exchange position (810).

24. The apparatus according to claim 8, wherein the at least one look-up camera (410) is arranged to make at least one second up-image (730) of a third component mark at the component exchange position (810); and
wherein the apparatus (100) is arranged to determine a position error of the component (600) using the at least one second up-image (730) and the at least one first up-image (720).

25. The apparatus according to claim 8, wherein the first component mark and the second component mark are physically different, physically similar, physically the same, physically identical, optically different, optically similar, optically the same, optically identical, or any combination thereof.
